(19) United States
(12) Patent Application Publication
(10) Pub. No.: US 2011/0001170 A1
(43) Pub. Date: Jan. 6, 2011

(54) SEMICONDUCTOR DEVICE AND METHOD OF MANUFACTURING SEMICONDUCTOR DEVICE

(75) Inventors: Takayuki Ito, Oita-ken (JP); Kunihiro Miyazaki, Oita-ken (JP); Kiyotaka Miyano, Tokyo (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/822,562

(22) Filed: Jun. 24, 2010

(30) Foreign Application Priority Data
Jul. 3, 2009 (JP) 2009-158503

(51) Int. Cl. H01L 29/04; H01L 21/336

(52) U.S. Cl. 257/255; 438/300; 257/E29.004; 257/E21.431

(57) ABSTRACT

A semiconductor device according to the embodiment includes an element region provided with a transistor, a plurality of mixed crystal layers, a drain electrode and a source electrode, an element isolation layer and a dummy pattern. The mixed crystal layers are the layers made of a first atom composing the semiconductor substrate and a second atom having a lattice constant different from the lattice constant of the first atom and formed on both ends of a region, which becomes a channel of the transistor. The dummy pattern is a layer made of the same material as the mixed crystal layers and formed to extend on the surface of the semiconductor substrate and outside of the element region such that a major direction thereof is different from a <110> direction of the semiconductor.

### CROSS REFERENCE TO RELATED APPLICATIONS

This application is based upon and claims the benefit of priority from the prior Japanese Patent Application No. 2009-158503 filed in Japan on Jul. 3, 2009; the entire contents of which are incorporated herein by reference.

### FIELD

Embodiments described herein relate generally to a semiconductor device having a mixed crystal layer and a method of manufacturing the same.

### BACKGROUND

Recently, further improvement in function of a transistor is demanded. In response to this demand, the transistor in which a mixed crystal layer having a lattice constant different from that of a substrate material is made a source region and a drain region is known. The transistor increases drain current by generating compression stress or tension stress in a channel region according to difference in lattice constant between the mixed crystal layer and the substrate material. Hereinafter, a structure of a p-channel type MOS field effect transistor (pMOSFET) is described as an example of a structure of the transistor of this type.

An n-type channel region is formed on a surface of a silicon substrate. In the channel region, concave portions ground by etching are formed so as to be spaced apart from each other. A p-type mixed crystal layer made of silicon germanium (SiGe) is formed in each of the concave portions by epitaxial growth. A source electrode or a drain electrode is formed on the mixed crystal layer. A gate electrode is formed on the channel region between the electrodes.

In such pMOSFET, the p-type mixed crystal layer is formed by injecting an impurity made of boron (B), for example, in a silicon germanium layer, and performing an annealing process. The annealing process when forming the p-type mixed crystal layer is performed by immediately supplying thermal energy using a flash lamp or a laser, for example, in order to achieve a balance between low resistance and shallow junction of the mixed crystal layer.

The above-described pMOSFET may obtain an effect of increasing the drain current by making concentration of germanium (Ge) contained in the p-type mixed crystal layer high or by making the mixed crystal layer larger.

However, when the mixed crystal layer in which the impurity such as germanium is contained with high concentration becomes thicker to be not thinner than a critical film thickness, displacement and crystal defect occur in the mixed crystal layer. Therefore, the compression stress applied to the channel region is relieved, so that there is a problem that the effect of increasing the drain current may not be sufficiently obtained.

Even when the formed mixed crystal layer is not thicker than the critical film thickness, the thermal stress increases in the silicon substrate at the time of the above-described annealing process and the displacement and the crystal defect occur in the silicon substrate by the thermal stress. Especially, the displacement and the crystal defect easily occur in the vicinity of a boundary surface between the silicon substrate and the mixed crystal layer. The displacement and the crystal defect occurring on the silicon substrate or on the boundary surface between the silicon substrate and the mixed crystal layer in this manner develop to the mixed crystal layer to relieve the compression stress applied to the channel region. Therefore, there is a problem that the effect of increasing the drain current may not be sufficiently obtained.

Further, when the displacement and the crystal defect occur in the mixed crystal layer, there is a problem that leak current (joining leak current) flowing from the mixed crystal layer, which becomes the drain region, in a depth direction of the silicon substrate increases.

There also is a problem similar to that described above in the case of an n-channel MOS field effect transistor (nMOSFET) formed by generating the tension stress in the channel region by epitaxially growing an n-type mixed crystal layer made of a silicon carbon (Si:C) layer.

### BRIEF DESCRIPTION OF DRAWINGS

FIG. 1 is a top view illustrating a semiconductor device according to an embodiment of the present invention;

FIG. 2 is a partial cross-sectional view of the device taken along a line X-X′ in FIG. 1;

FIG. 3 is a view for illustrating a step of forming a well layer, which is a step of manufacturing the semiconductor device according to the embodiment of the present invention, and is a cross-sectional view corresponding to FIG. 2;

FIG. 4 is a view for illustrating a step of forming an element isolation layer, which is a step of manufacturing the semiconductor device according to the embodiment of the present invention, and is a cross-sectional view corresponding to FIG. 2;

FIG. 5 is also a view for illustrating the step of forming the element isolation layer, which is a step of manufacturing the semiconductor device according to the embodiment of the present invention, and is a cross-sectional view corresponding to FIG. 2;

FIG. 6 is a view for illustrating a step of forming a gate electrode, which is a step of manufacturing the semiconductor device according to the embodiment of the present invention, and is a cross-sectional view corresponding to FIG. 2;

FIG. 7 is also a view for illustrating the step of forming the gate electrode, which is a step of manufacturing the semiconductor device according to the embodiment of the present invention, and is a cross-sectional view corresponding to FIG. 2;

FIG. 8 is a view for illustrating a step of forming a mixed crystal layer, which is a step of manufacturing the semiconductor device according to the embodiment of the present invention, and is a cross-sectional view corresponding to FIG. 2;

FIG. 9 is a view for illustrating a step of forming a dummy pattern, which is a step of manufacturing the semiconductor device according to the embodiment of the present invention, and is a partial cross-sectional view of the device taken along a line Y-Y′ in FIG. 1;

FIG. 10 is also a view for illustrating the step of forming the mixed crystal layer, which is a step of manufacturing the semiconductor device according to the embodiment of the present invention, and is a cross-sectional view corresponding to FIG. 2;

FIG. 11 is also a view for illustrating the step of forming the dummy pattern, which is a step of manufacturing the semiconductor device according to the embodiment of the present invention, and is a partial cross-sectional view of the device taken along the line Y-Y′ in FIG. 1;

FIG. 12 is also a view for illustrating the step of forming the mixed crystal layer, which is a step of manufacturing the semiconductor device according to the embodiment of the present invention, and is a cross-sectional view corresponding to FIG. 2;

FIG. 13 is also a view for illustrating the step of forming the dummy pattern, which is a step of manufacturing the semiconductor device according to the embodiment of the present invention, and is a partial cross-sectional view of the device taken along the line Y-Y′ in FIG. 1;

FIG. 14 is a view for illustrating a step of forming a drain region and a source region, which is a step of manufacturing the semiconductor device according to the embodiment of the present invention, and is a cross-sectional view corresponding to FIG. 2;

FIG. 15 is also a view for illustrating the step of forming the drain region and the source region, which is a step of manufacturing the semiconductor device according to the embodiment of the present invention, and is a cross-sectional view corresponding to FIG. 2;

FIG. 16 is also a view for illustrating the step of forming the drain region and the source region, which is a step of manufacturing the semiconductor device according to the embodiment of the present invention, and is a cross-sectional view corresponding to FIG. 2;

FIG. 17 is also a view for illustrating the step of forming the drain region and the source region, which is a step of manufacturing the semiconductor device according to the embodiment of the present invention, and is a cross-sectional view corresponding to FIG. 2;

FIG. 18 is a view for illustrating a step of performing a thermal process to the drain region and the source region, which is a step of manufacturing the semiconductor device according to the embodiment of the present invention, and is a cross-sectional view corresponding to FIG. 2;

FIG. 19 is a view for illustrating a temperature profile of a lamp used for performing an activation annealing process to the drain region and the source region of the semiconductor device according to the embodiment of the present invention;

FIG. 20 is a view for illustrating a step of forming the drain region and the source region, which is a step of manufacturing the semiconductor device according to the embodiment of the present invention, and is a cross-sectional view corresponding to FIG. 2;

FIG. 21 is a view for illustrating a step of forming a CMOSFET, which is a step of manufacturing the semiconductor device according to the embodiment of the present invention, and is a cross-sectional view corresponding to FIG. 2;

FIG. 22 is a top view illustrating the semiconductor device according to another embodiment of the present invention;

FIG. 23 is a top view illustrating the semiconductor device according to another embodiment of the present invention; and

FIG. 24 is a top view illustrating the semiconductor device according to another embodiment of the present invention.

### DETAILED DESCRIPTION

A semiconductor device and a method of manufacturing the same according to an embodiment are hereinafter described. The semiconductor device according to the embodiment includes an element region provided with a transistor, a plurality of mixed crystal layers, a drain electrode and a source electrode, an element isolation layer and a dummy pattern. The transistor is a second conductive-type transistor formed on a surface of a semiconductor substrate and having a gate electrode and first conductive-type drain region and source region. The mixed crystal layers are the layers made of a first atom composing the semiconductor substrate and a second atom having a lattice constant different from the lattice constant of the first atom and formed on both ends of a region, which becomes a channel of the transistor. The drain electrode is the electrode formed on the drain region and the source electrode is the electrode formed on the source region. The element isolation layer is the layer formed on the surface of the semiconductor substrate so as to enclose the element region. The dummy pattern is a layer made of the same material as the mixed crystal layers and formed to extend on the surface of the semiconductor substrate and outside of the element region such that a major direction thereof is different from a <110> direction of the semiconductor substrate. The semiconductor device is hereinafter specifically described with reference to the drawings.

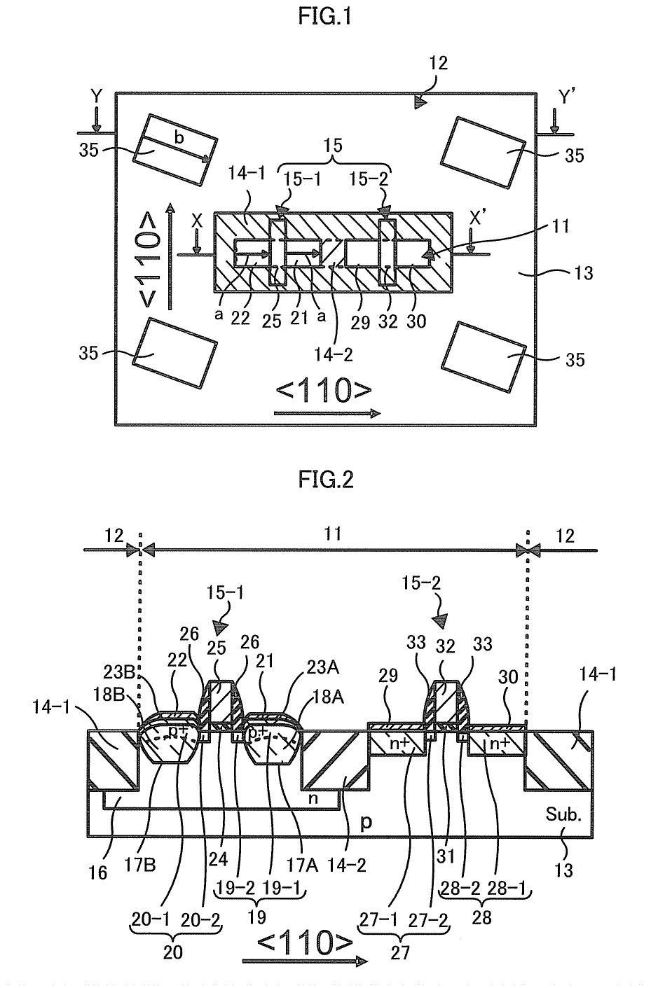

FIG. 1 is a top view illustrating a semiconductor device according to this embodiment. As illustrated in FIG. 1, the semiconductor device according to this embodiment has an element region 11 and a non-element region 12 on a surface of a p-type silicon substrate 13, which is the semiconductor substrate. The regions 11 and 12 are electrically isolated from each other by an element isolation layer 14-1 formed into a frame shape on the surface of the p-type silicon substrate 13. In the following description, the element isolation layer 14-1 is referred to as a first element isolation layer 14-1.

The element region 11 is an inner region of the first element isolation layer 14-1. The inside of the first element isolation layer 14-1 is further isolated by a second element isolation layer 14-2. Each of the first and second element isolation layers 14-1 and 14-2 has a shallow trench isolation (STI) structure, for example. The STI structure is obtained by grinding the surface of the silicon substrate 13 into a concave shape and embedding an insulating film of SiO₂ and the like, for example, in the ground concave-shaped portion.

In one element region 11 isolated by the second element isolation layer 14-2, a pMOSFET 15-1, for example, is formed as the transistor. In the other element region 11, an nMOSFET 15-2 is formed. Each of the pMOSFET 15-1 and the nMOSFET 15-2 is formed such that a channel direction thereof is in a crystal axis <110> direction of the silicon substrate 13 as indicated by an arrow a in the drawing.

The pMOSFET 15-1 and the nMOSFET 15-2 in the first element isolation layer 14-1 compose a CMOSFET 15. The CMOSFET 15 is composed by appropriate electric connection of the pMOSFET 15-1 and the nMOSFET 15-2 by wiring formed above the pMOSFET 15-1 and the nMOSFET 15-2 as described above. That is to say, in the first element isolation layer 14-1, the CMOSFET 15 is formed.

FIG. 2 is a partial cross-sectional view of the device taken along a line X-X′ in FIG. 1. A structure of the element region 11, especially, a structure of the pMOSFET 15-1 is hereinafter described with reference to FIG. 2.

As illustrated in FIG. 2, an n-type well layer 16, which serves as a channel region of the pMOSFET 15-1, is formed on the surface of one silicon substrate 13 enclosed by the first element isolation layer 14-1 and the second element isolation layer 14-2. The n-type well layer 16 is formed such that a channel direction thereof is in the crystal axis <110> direction of the silicon substrate 13.

Recess regions 17A and 17B provided so as to have the concave shapes in order to form a part of a drain region 19 and a source region 20 are formed on a surface of the well layer 16 so as to be spaced apart from each other. On one recess region 17A, a mixed crystal layer 18A rising above from the silicon substrate 13 by epitaxial growth is formed. On a surface of the mixed crystal 18A, a p+-type impurity injection layer 19-1 is formed. Similarly, on the other recess region 17B, a mixed crystal layer 18B rising above from the silicon substrate 13 by the epitaxial growth is formed. A p+-type impurity injection layer 20-1 is formed on a surface of the mixed crystal layer 18B.

Further, a p-type impurity injection layer 19-2 joined with the p+-type impurity injection layer 19-1 is formed on the surface of the silicon substrate 13. The p-type impurity injection layer 19-2 is formed to be shallower than the p+-type impurity injection layer 19-1. Similarly, a p-type impurity injection layer 20-2 joined with the p+-type impurity injection layer 20-1 is formed on the surface of the silicon substrate 13. The impurity injection layer 20-2 is also formed to be shallower than the p+-type impurity injection layer 20-1. The p-type impurity injection layers 19-2 and 20-2 are formed so as to be spaced apart from each other.

A drain region 19 is composed of the p+-type impurity injection layer 19-1 and the p-type impurity injection layer 19-2 joined with the same. Also, a source region 20 is composed of the p+-type impurity injection layer 20-1 and the p-type impurity injection layer 20-2 joined with the same.

Herein, each of the above-described mixed crystal layers 18A and 18B is made of SiGe, for example. Specifically, this is made of SiGe containing Si as the first atom and Ge as the second atom in which Ge concentration is 25%. However, the concentration of Ge in each of the mixed crystal layers 18A and 185 preferably increases in a direction from the surface toward an inner portion of each of the mixed crystal layers 18A and 18B. That is to say, for example, the mixed crystal layer 18A is preferably formed such that the concentration is 0 to 25% in the vicinity of a boundary surface between the recess region 17A and a lower surface of the mixed crystal layer 18A, 25 to 15% in the vicinity of the center of the inner portion of the mixed crystal layer 18A and 15 to 0% in the vicinity of an upper surface of the mixed crystal layer 18A rising from the silicon substrate 13. It is preferable that the mixed crystal layer 18B is similarly formed.

In this manner, by forming the mixed crystal layers 18A and 18B such that the Ge concentration in each of the mixed crystal layers 18A and 18B gradually increases in a direction from the lower surface of each of the mixed crystal layers 18A and 18B toward the center of the mixed crystal layer 18, occurrence of peripheral displacement and crystal defect of the mixed crystal layers 18A and 18B attributed to lattice mismatch between the silicon substrate 13 and the mixed crystal layers 18A and 18B is inhibited. Therefore, stress by the mixed crystal layers 18A and 18B may be effectively applied to the well layer 16.

Further, by forming the mixed crystal layers 18A and 18B such that the Ge concentration gradually decreases from the center toward the upper surface of each of the mixed crystal layers 18A and 18B, Si concentration on the upper surface of each of the mixed crystal layers 18A and 18B may be made the concentration with which silicide reaction with the drain electrode 21 and the source electrode 22 to be described later is easily obtained. Therefore, excellent contact between the upper surface of the mixed crystal layer 18A and the drain electrode 21 and between the upper surface of the mixed crystal layer 18B and the source electrode 22 is realized.

Each of such mixed crystal layers 18A and 18B is formed such that a horizontal cross-sectional shape thereof relative to the silicon substrate 13 is a rectangle, for example, as illustrated in FIG. 1. Each of the mixed crystal layers 18A and 18B is formed such that a major direction (direction indicated by the arrow a in FIG. 1) is in the crystal axis <110> direction of the silicon substrate 13. The above-described major direction is herein intended to mean a direction parallel to a longitudinal side of the rectangle.

In this application, the rectangle is intended to mean a substantial rectangle including a shape with a round corner, for example, in addition to a perfect rectangle of which four corners are 90 degrees.

In this application, the horizontal cross-sectional shape of each of the mixed crystal layers 18A and 18B may be an ellipse, for example. In this case, the major direction is intended to mean a direction parallel to a longitudinal axis of the ellipse. Such mixed crystal layers 18A and 18B may also be formed such that the major directions thereof are in the crystal axis <110> direction of the silicon substrate 13.

The horizontal cross-sectional shape of each of the mixed crystal layers 18A and 18B is not limited, and this may be any shape formed so as to extend the longest in a certain direction. The certain direction is defined as the major direction of the shape. In this manner, the mixed crystal layers 18A and 18B with optional horizontal cross-sectional shapes are also formed such that the major directions thereof are in the crystal axis <110> direction of the silicon substrate 13.

The drain electrode 21 made of high-melting point metal such as nickel platinum (NiPt) is formed on the above-described mixed crystal layer 18A. The electrode 21 is formed on the mixed crystal layer 18A through a suicide layer 23A, which is silicized, on the upper surface of the mixed crystal layer 18A. Similarly, the source electrode 22 made of the same material as the drain electrode 21 is formed on the mixed crystal layer 18B. The electrode 22 is also formed on the mixed crystal layer 18B through a silicide layer 23B, which is silicized, on the upper surface of the mixed crystal layer 18B. Further, on the surface of the well layer 16, a gate electrode 25 is formed between the drain region 19 and the source region 20 through a gate insulating film 24 as illustrated in FIG. 2. The gate electrode 25 is formed into a band shape so as to get across the well layer 16 as illustrated in FIG. 1.

The gate insulating film 24 is made of a thermal oxynitride film (Si oxynitride film), for example, and the gate electrode 25 is made of polysilicon, for example. However, the gate insulating film 24 may be an oxide film such as a SiO₂ film or a metal oxide film containing hafnium (Hf), aluminum (Al) and the like. Also, the gate electrode 24 may be polysilicon containing a metal material.

Gate side walls 26 made of SiO₂, for example, are formed on both side walls of the gate electrode 24 including the gate insulating film 24.

Next, a structure of the nMOSFET 15-2 is described. As illustrated in FIG. 2, the surface of the other silicon substrate 13 enclosed by the first and second element isolation layers 14-1 and 14-2 serves as a channel region of the nMOSFET 15-2. An n+-type impurity injection layer 27-1 and an n-type impurity injection layer 27-2 shallower than the n+-type impurity injection layer 27-1 are formed on the surface of such silicon substrate 13. The impurity injection layers 27-1 and 27-2 are formed so as to be joined with each other, thereby forming a drain region 27. Similarly, on the surface of the silicon substrate 13, on a portion spaced apart from the drain region 27, an n+-type impurity injection layer 28-1 and an n-type impurity injection layer 28-2 shallower than the n+-type impurity injection layer 28-1 are formed. The impurity injection layers 28-1 and 28-2 are formed so as to be joined with each other, thereby forming a source region 28.

On the above-described n+-type impurity injection layer 27-1, a drain electrode 29 made of high-melting point metal such as nickel platinum (NiPt) is formed. Similarly, on the n+-type impurity injection layer 28-1, a source electrode 30 made of the same material as the drain electrode 29 is formed.

Further, on the surface of the silicon substrate 13, a gate electrode 32 is formed between the drain region 27 and the source region 28 through a gate insulating film 31 as illustrated in FIG. 2. The gate electrode 32 is formed into a band shape so as to get across the region enclosed by the first and second element isolation layers 14-1 and 14-2 as illustrated in FIG. 1. Gate side walls 33 are formed on both side walls of the gate electrode 32.

The gate insulating film 31, the gate electrode 32 and the gate side walls 33 are formed of the same material as the above-described gate insulating film 24, gate electrode 25 and gate side walls 26 of the pMOSFET, respectively.

On the silicon substrate 13 on which the above-described pMOSFET 15-1 and nMOSFET 15-2 are formed, an interlayer insulating film (not illustrated in FIGS. 1 and 2) is formed, and a wiring layer (not illustrated) is formed on the interlayer insulating film. The above-described pMOSFET 15-1 and nMOSFET 15-2 are electrically connected to wiring (not illustrated) formed in the wiring layer through a via (not illustrated) formed in a plurality of contact holes (not illustrated in FIGS. 1 and 2) formed in the interlayer insulating film.

Specifically, the gate electrode 25 of the pMOSFET 15-1 and the gate electrode 32 of the nMOSFET 15-2 are connected in common to the wiring connected to an input terminal (not illustrated) through the via (not illustrated) formed in the contact hole. Similarly, the drain electrode 21 of the pMOSFET 15-1 and the drain electrode 29 of the nMOSFET 15-2 are connected in common to the wiring connected to an output terminal (not illustrated) through the via (not illustrated) formed in the contact hole. Also, the source electrode 22 of the pMOSFET 15-1 is connected to the wiring connected to a power supply (not illustrated) through the via (not illustrated) formed in the contact hole and the source electrode 30 of the nMOSFET 15-2 is grounded through the wiring connected through the contact hole.

That is to say, the element region 11 already described may also be defined as the region electrically connected to the wiring layer formed above the region 11. On the other hand, the non-element region 12 to be described hereinafter may also be defined as the region, which is not electrically connected to the wiring layer.

Next, the non-element region 12 illustrated in FIG. 1 is described.

A plurality of rectangular dummy patterns 35 having longitudinal sides of approximately 1 μm, for example, are formed in a lattice pattern on the non-element region 12. Each of the dummy patterns is the mixed crystal layer formed of the same material (SiGe) by the same forming method to have the same Ge concentration as the mixed crystal layers 18A and 18B of the element region 11 illustrated in FIG. 2.

Such dummy patterns 35 are formed in a plurality of recess regions (not illustrated in FIG. 2) each formed to have the concave shape on the surface of the non-element region 12 as the recess regions 17A and 17B illustrated in FIG. 2.

The dummy patterns 35 are provided so as to realize stable epitaxial growth when forming the mixed crystal layers 18A and 18B of the above-described element region 11.

That is to say, surface areas of the mixed crystal layers 18A and 18B of the above-described element region 11 are extremely small as compared to the surface area of the silicon substrate 13. The epitaxial growth generally has a problem that a film is not normally formed when a coverage of the epitaxial layer relative to the silicon substrate 13 is extremely small and a film thickness differs depending on a portion of the film formation. Therefore, the dummy patterns 35 are provided so as to increase the coverage of the surface area of the epitaxial layer relative to the surface area of the silicon substrate 13. According to this, the stable epitaxial growth is realized when forming the mixed crystal layers 18A and 18B of the element region 11.

The above-described coverage have the same meaning as an aperture ratio, which is a ratio of areas of all the recess regions to the surface area of the silicon substrate 13, and in the semiconductor device of this embodiment, the coverage, that is to say, the aperture ratio is 10%, for example.

Each of such dummy patterns 35 is formed such that the major direction (arrow b in the drawing) of the dummy pattern 35 is different from the crystal axis <110> direction of the silicon substrate 13 as illustrated in FIG. 1 in order to inhibit the displacement and the crystal defect occurring in the dummy patterns 35. A reason for this is to be described later.

The horizontal cross-sectional shape of the dummy pattern 35 is not limited to the rectangle as the horizontal cross-sectional shapes of the mixed crystal layers 18A and 18B, and may be the ellipse, for example. Also in this case, the dummy pattern 35 may be formed such that the major direction thereof is different from the crystal axis <110> direction of the silicon substrate 13.

Definition of the major direction of the dummy pattern 35 is similar to the definition of the major direction of the mixed crystal layers 18A and 18B, so that the description thereof will not be repeated here.

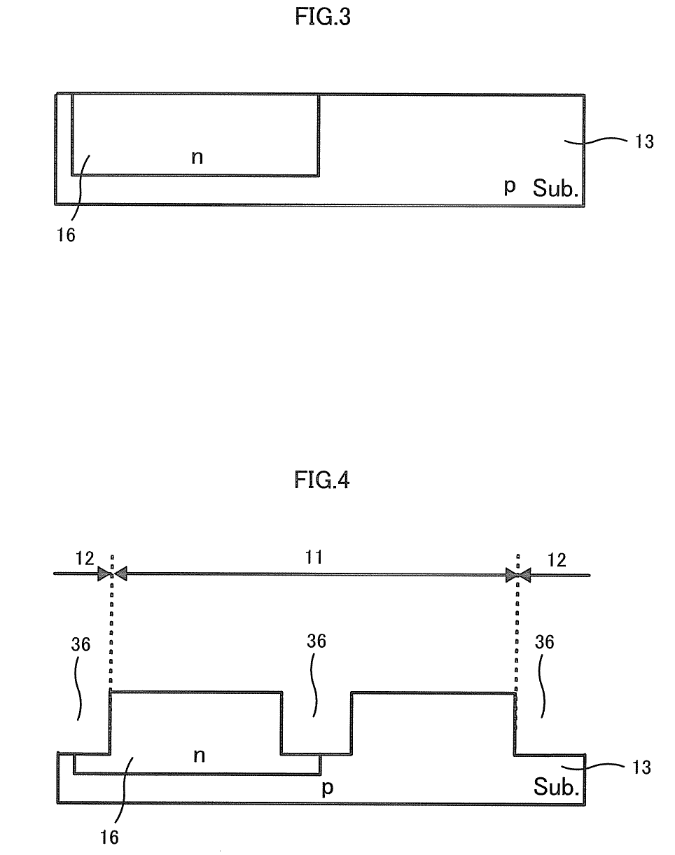

Next, the method of manufacturing the above-described semiconductor device is described. The method of manufacturing the above-described semiconductor device is the method provided with a step of forming the element isolation layer, a step of forming a first impurity injection layer, a step of forming the gate electrode, a step of forming a first recess region, a step of forming a second recess region, a step of epitaxially growing the mixed crystal layer and the dummy pattern, a step of forming a second impurity injection layer and a step of forming the drain electrode and the source electrode. The step of forming the element isolation layer is the step of forming the element isolation layer for electrically isolating the element region and the non-element region on the surface of the semiconductor substrate. The step of forming the first impurity injection layer is the step of forming the first conductive-type impurity injection layer on the surface of the element region. The step of forming the gate electrode is the step of forming the gate electrode on the first conductive-type impurity injection layer. The step of forming the first recess region is the step of forming the first recess region on both ends of the region under the gate electrode out of the semiconductor substrate. The step of forming the second recess region is the step of forming the second recess region on the non-element region. The step of epitaxially growing the mixed crystal layer and the dummy pattern is the step of epitaxially growing the mixed crystal layer made of the first atom composing the semiconductor substrate and the second atom having the lattice constant different from the lattice constant of the first atom in the first recess region and at the same time epitaxially growing the dummy pattern made of the same material as the mixed crystal layer in the second recess region such that the major direction of the dummy pattern is different from the <110> direction of the semiconductor substrate. The step of forming the second impurity injection layer is the step of forming a second conductive-type impurity injection layer on the surface of the mixed crystal layer. The step of forming the drain electrode and the source electrode is the step of forming the drain electrode and the source electrode on the second conductive-type impurity injection layer. The method is hereinafter specifically described with reference to FIGS. 3 to 21. First, the method of manufacturing the semiconductor device until forming the gate electrodes 25 and 32 is described with reference to FIGS. 3 to 7. FIGS. 3 to 7 are views for illustrating the method of manufacturing the semiconductor device and are cross-sectional views corresponding to FIG. 2.

First, as illustrated in FIG. 3, the n-well layer 16 is formed on a part of the surface of the silicon substrate 13. The well layer 16 is formed by providing a photo resist film (not illustrated) having an aperture in a region in which the pMOSFET 15-1 illustrated in FIG. 1 is formed on the surface of the silicon substrate 13 and performing ion injection of a group V atom of an n-type impurity, such as phosphorous (P) in the silicon substrate 13 by using the photo resist film as a mask.

Next, as illustrated in FIG. 4, after removing the photo resist film from the silicon substrate 13, a trench 36 is formed on the silicon substrate 13 so as to enclose a region in which the pMOSFET 15-1 and the nMOSFET 15-2 illustrated in FIG. 1 are formed. At the same time, the trench 36 is formed so as to isolate the region in which the pMOSFET 15-1 is formed and the region in which the nMOSFET 15-2 is formed. The trenches 36 are formed by means of photolithography and reactive ion etching (RIE), for example.

Next, as illustrated in FIG. 5, an insulating film (not illustrated) of SiO₂ and the like is deposited on the silicon substrate 13 so as to infill at least the inside of the trench 36. Thereafter, by removing the insulating film from the surface of the silicon substrate 13, the first and second element isolation layers 14-1 and 14-2 each having the shallow trench isolation (STI) structure are formed.

Deposition of the insulating film is performed by a low pressure chemical vapor deposition (LPCVD) method, for example. Also, removal of the insulating film is performed by a chemical mechanical polishing (CMP) method, for example.

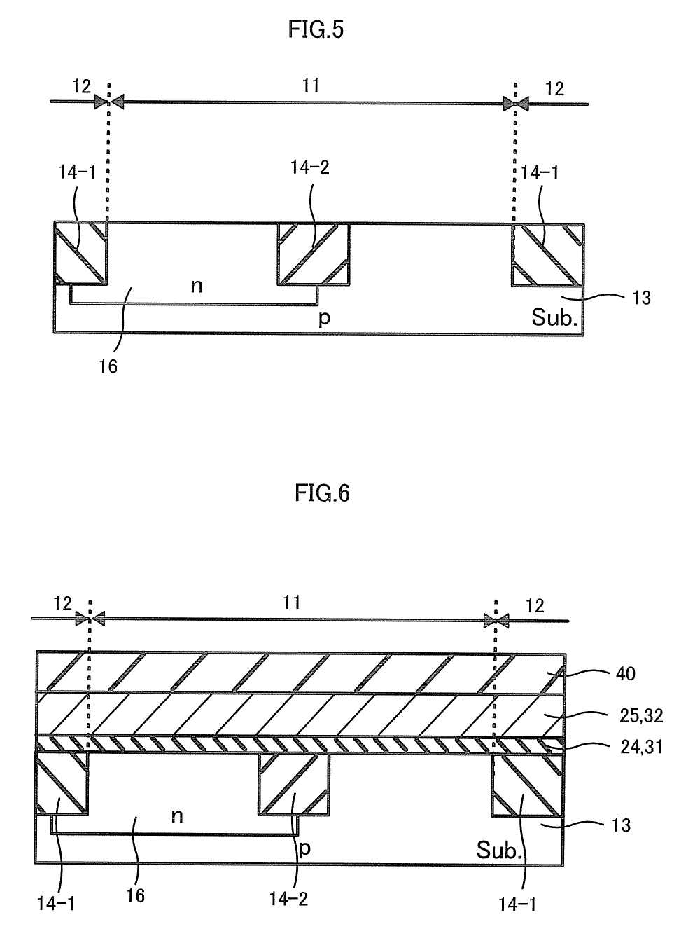

Next, as illustrated in FIG. 6, the thermal oxynitride film (Si oxynitride film), which becomes the gate insulating films 24 and 31 later, a polysilicon film, which becomes the gate electrodes 25 and 32 later, and a silicon nitride film (Si₃N₄), which becomes an offset insulating film 40 later, are deposited in this order on an entire surface of the silicon substrate 13. The films are deposited by the LPCVD method, for example.

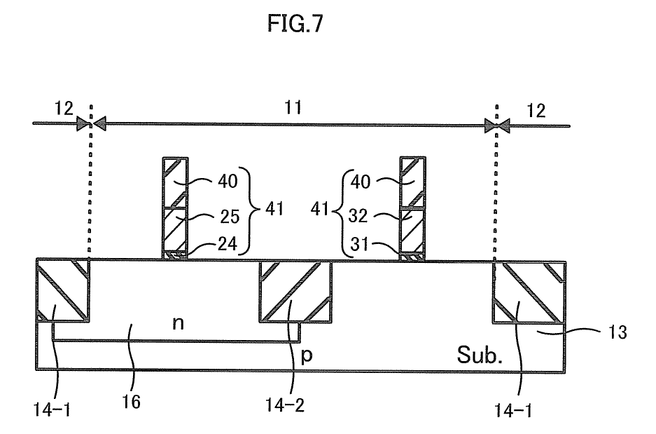

Next, as illustrated in FIG. 7, band-shaped laminated structure bodies 41 obtained by laminating the gate insulating film 24, the gate electrode 25 and the offset insulating film 40 on the well layer 16 including the first element isolation layer 14-1 in this order and by laminating the gate insulating film 31, the gate electrode 32 and the offset insulating film 40 in this order on the silicon substrate 13 including the first element isolation layer 14-1 are formed. The laminated structure bodies 41 are formed by removing the film deposited at the step illustrated in FIG. 6 by means of the photolithography and the RIE such that a part thereof is left in the band-shape.

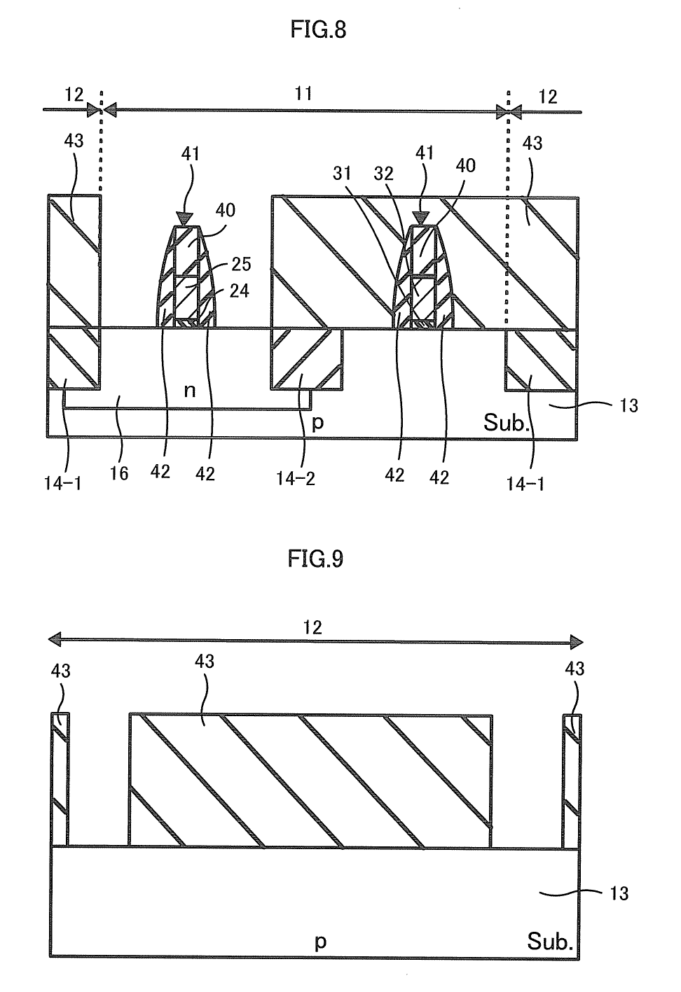

Next, with reference to FIGS. 8 to 13, the method of manufacturing the semiconductor device until forming the mixed crystal layers 18A and 18B and the dummy pattern 35 is described. FIGS. 8, 10 and 12 are views for illustrating the method of manufacturing the semiconductor device and are cross sectional views corresponding to FIG. 2. Also, FIGS. 9, 11 and 13 are views for illustrating the method of manufacturing the semiconductor device and the cross-sectional views of the device taken along a line Y-Y′ in FIG. 1.

First, as illustrated in FIG. 8, gate side walls are formed on side walls of the band-shaped laminated structure body 41. Thereafter, as illustrated in FIGS. 8 and 9, a photo resist film 43 having apertures on a part of the well layer 16 and the non-element region 12 is formed on the silicon substrate 13.

The gate side walls 42 are formed in the following manner, for example. First, a Si oxide film is formed, for example, on the silicon substrate 13 so as to cover the band-shaped laminated structure 41. Then, the Si oxide film is etched back. According to this, the gate side walls 42 are formed on the side walls of the laminated structure body 41. The film formed so as to form the gate side walls 42 illustrated in FIG. 8 may be the Si nitride film, for example, or a laminated film obtained by laminating the Si oxide film and the Si nitride film, in addition to the Si oxide film.

The films formed for forming the gate side walls 42 are formed by means of the LPCVD method, for example. Also, the etch-back is performed by means of an anisotropic dry etching method such as the RIE.

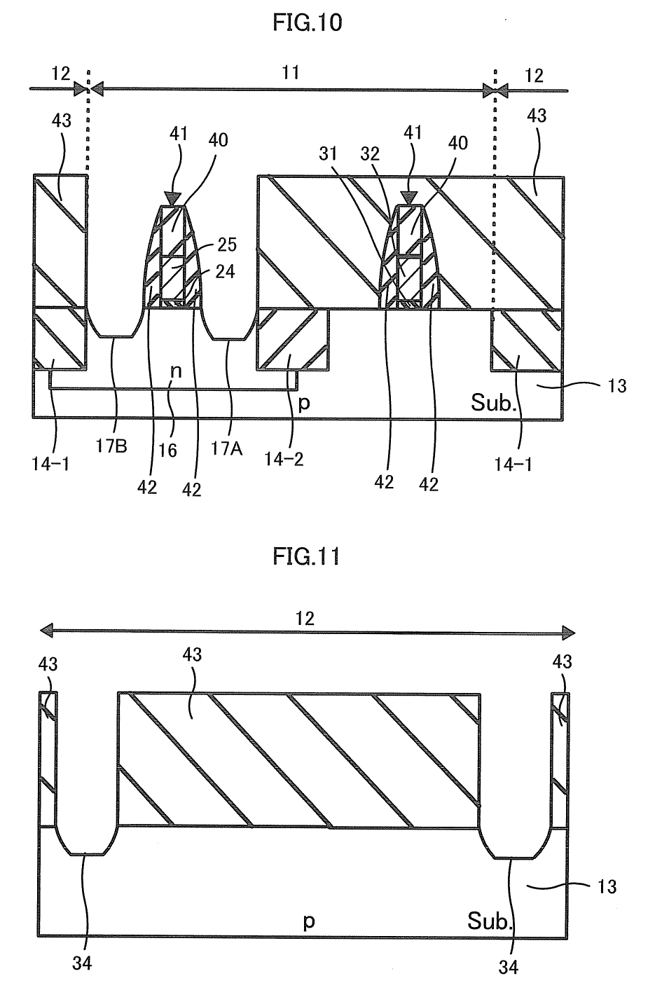

Next, as illustrated in FIGS. 10 and 11, recess etching is applied to the surface of the silicon substrate 13 by using the offset insulating film 40, the gate side walls 42 and the photo resist film 43 as the mask. According to this, the concave-shaped recess regions 17A, 17B and 34 are formed on the surface of the silicon substrate 13. The recess regions 17A, 17B and 34 are formed to have a depth of approximately 80 nm, for example. Further, the recess regions 17A, 17B and 34 are formed such that the aperture ratio, which is the ratio of the total area of all the recess regions 17A, 17B and 34 to the surface area of the silicon substrate 13 is 10%.

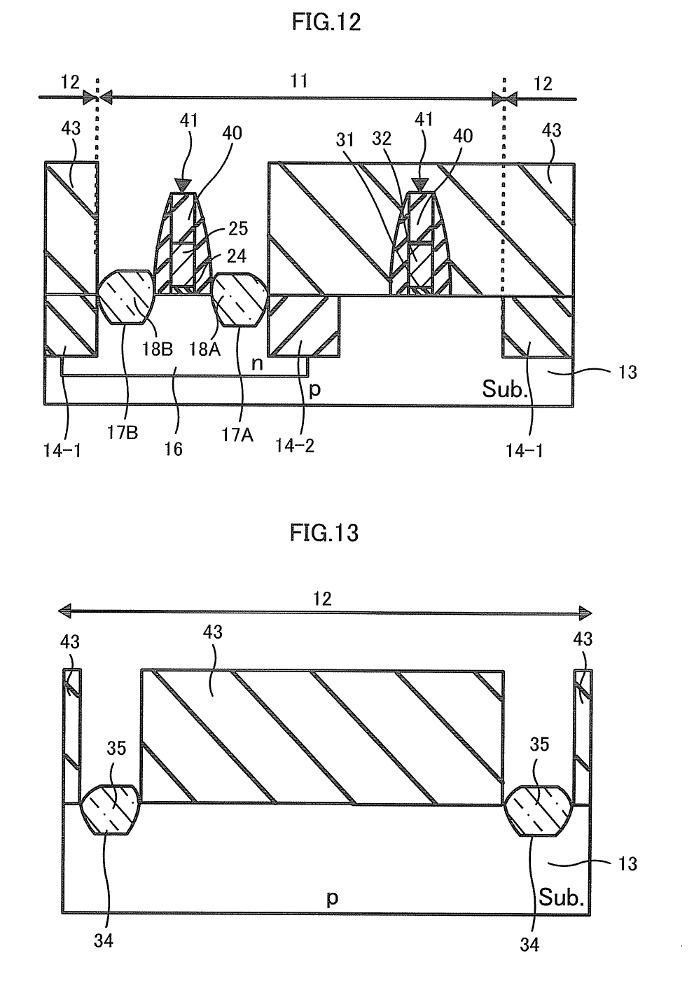

Next, after removing a natural oxide film on the surface of the silicon substrate 13 by a cleaning process using diluted hydrofluoric acid, as illustrated in FIG. 12, the mixed crystal layers 18A and 18B made of Si and Ge of which lattice constant is larger than that of Si are epitaxially grown on the recess regions 17A and 17B. At the same time, as illustrated in FIG. 13, the dummy pattern 35 formed of the same material as the mixed crystal layers 18A and 18B is epitaxially grown in the recess region 34.

At this step, the mixed crystal layer 18 illustrated in FIG. 12 is formed such that the major direction thereof is in the crystal axis <110> direction of the silicon substrate 13. Also, the dummy pattern 35 illustrated in FIG. 13, that is to say, the mixed crystal layer 35 in the non-element region is formed such that the major direction thereof is different from the crystal axis <110> direction of the silicon substrate 13. Especially, a reason for forming the dummy pattern 35 in this manner is to be described later.

It is preferable that each of the above-described mixed crystal layers 18A and 18B and the dummy pattern 35 is formed such that the Ge concentration therein increases in a direction from the surface toward the inner portion thereof as described above. Such mixed crystal layers 18A and 18B and the dumpy pattern 35 may be formed by gradually increasing a gas flow amount of GeH₄, which is film-formation gas used at the time of the epitaxial growth, as the Ge concentration is increased, and by gradually decreasing the gas flow amount as the Ge concentration is decreased.

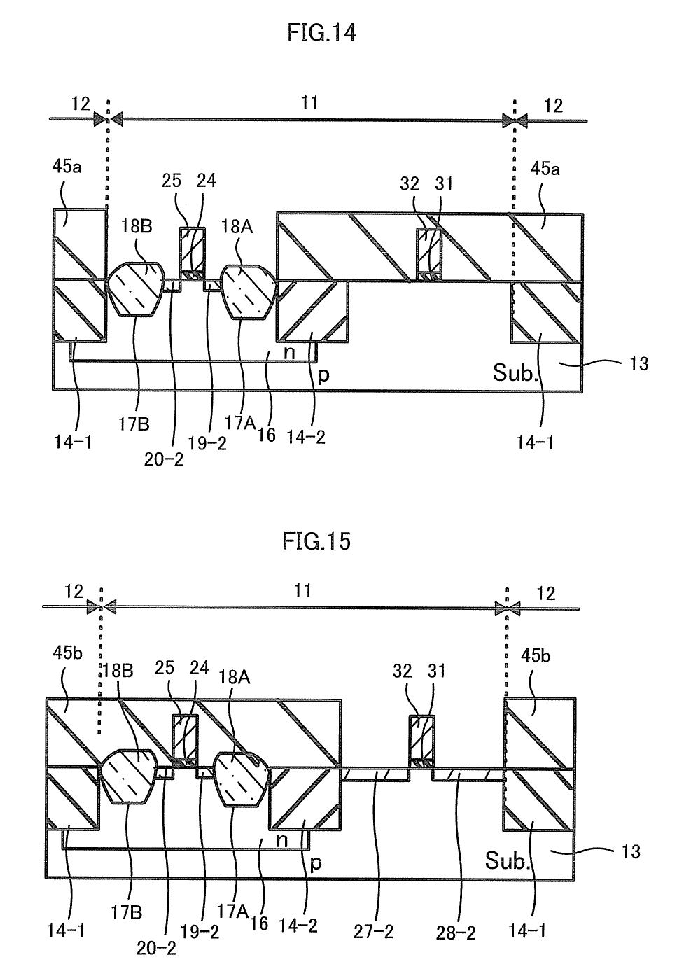

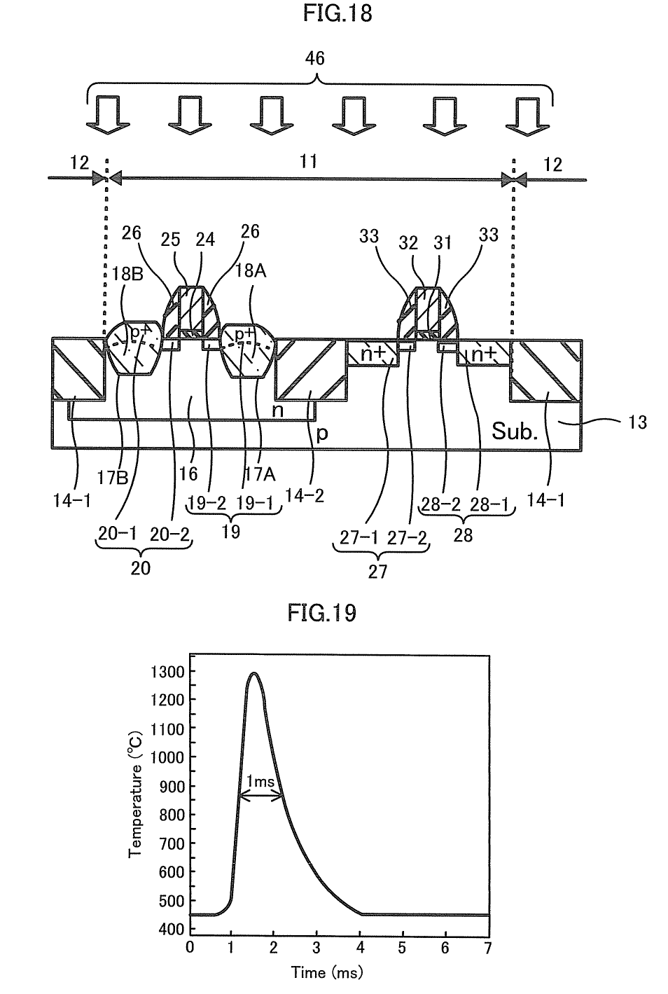

Next, with reference to FIGS. 14 to 21, the method of manufacturing until the semiconductor device is completed is described. FIGS. 14 to 21 except FIG. 19 are views for illustrating the method of manufacturing the semiconductor device and are cross-sectional views corresponding to FIG. 2. FIG. 19 illustrates a temperature profile of a lamp used at an activation annealing step, which is one manufacturing step of the semiconductor device.

First, the photo resist film 43 illustrated in FIGS. 12 and 13 is removed, and further, the offset insulating film 40 and the gate side walls 42 are removed by drug solution. Thereafter, as illustrated in FIG. 14, out of the two regions enclosed by the first element isolation layer 14-1 and the second element isolation layer 14-2, other than the regions in which the mixed crystal layers 18A and 18B and the gate electrode 25 are formed is covered with a photo resist film 45a, for example. Then, a group III atom such as BF₂, which becomes a p-type impurity, is injected by using the photo resist film 45a as the mask. An injection condition of BF₂ is, for example, acceleration energy of 2 keV and a dose amount of 1×10¹⁵ cm⁻². According to this, the p-type impurity injection layers 19-2 and 20-2 are formed on the surface of the silicon substrate 13 between the mixed crystal layers 18A and 18B and the gate electrode 25, respectively.

Although the p-type impurity injection layer is also formed on the surface of each of the mixed crystal layers 18A and 18B at this step, they are not illustrated.

Next, after removing the photo resist film 45a illustrated in FIG. 14, as illustrated in FIG. 15, out of the region enclosed by the first element isolation layer 14-1 and the second element isolation layer 14-2, other than the region in which the gate electrode 32 is formed is covered with the photo resist film 45b, for example. Then, a group V atom such as arsenic (As) ion, which becomes the n-type impurity, is injected by using the photo resist film 45b as the mask. The injection condition of the As ion is the acceleration energy of 2 keV and the dose amount of 1×10¹⁵ cm⁻², for example. According to this, the n-type impurity injection layers 27-2 and 28-2 are formed on the surface of the silicon substrate 13.

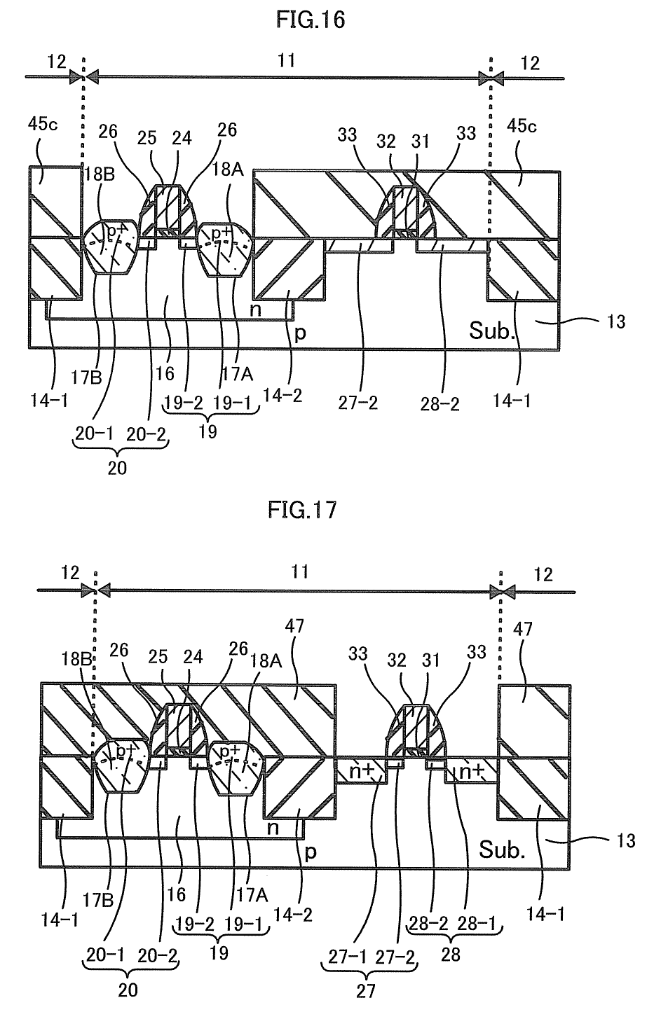

Next, after removing the photo resist film 45b illustrated in FIG. 15, as illustrated in FIG. 16, multilayer structure gate side walls 26 made of the Si oxide film and the Si nitride film, for example, are formed on side walls of the gate insulating film and the gate electrode 25, and multilayer structure gate side walls 33 made of the Si oxide film and the Si nitride film, for example, are formed on side walls of the gate insulating film 31 and the gate electrode 32, as the gate side walls 42 illustrated in FIG. 8. Thereafter, out of the two regions enclosed by the first element isolation layer 14-1 and the second element isolation layer 14-2, other than the regions in which a first mixed crystal layer 18 and the gate electrode 25 are formed is covered again with a photo resist film 45c, for example. Then, the p-type impurity made of boron (B) is injected, for example, by means of an ion injection method by using the gate side walls 26 and the photo resist film 45c as the mask. The injection condition of the B ion is the acceleration energy of 2 keV and the dose amount of 3×10¹⁵ cm⁻², for example. According to this, the p+-type impurity injection layers 19-1 and 20-1 are formed on the surfaces of the mixed crystal layers 18A and 18B, respectively.

Next, after removing the photo resist film 45c illustrated in FIG. 16, as illustrated in FIG. 17, out of the region enclosed by the first element isolation layer 14-1 and the second element isolation layer 14-2, other than the region in which the gate electrode 32 is formed is covered again with a photo resist film 47, for example. Then, the n-type impurity made of arsenic (As) is injected, for example, by the ion injection method by using the gate side walls 33 and the photo resist film 47 as the mask. The condition of the As ion injection is the acceleration energy of 20 keV and the dose amount of 3×10¹⁵ cm⁻², for example. According to this, the n+-type impurity injection layers 27-1 and 28-1 are formed on the silicon substrate 13, respectively.

Next, as illustrated in FIG. 18, after removing the photo resist film 47, an annealing process is applied to the device by spike rapid thermal annealing (RTA) using light 46 emitted from a halogen lamp at 1050° C., for example. By the annealing process, boron injected to the p+-type impurity injection layers 19-1 and 20-1 is substituted at a lattice position and is introduced. Therefore, the crystal defect occurring in the mixed crystal layers 18A and 18B by the ion injection is recovered.

After that, the activation annealing is performed by using a flash lamp having the temperature profile illustrated in FIG. 19. According to this, the p+-type impurity injection layers 19-1 and 20-1 are electrically activated. A temperature increasing/decreasing rate of the flash lamp is not lower than 10⁵° C./sec.

Herein, an activation annealing temperature is 1200° C., for example. The activation annealing temperature is preferably not lower than 1150° C. and more preferably not lower than 1200° C.

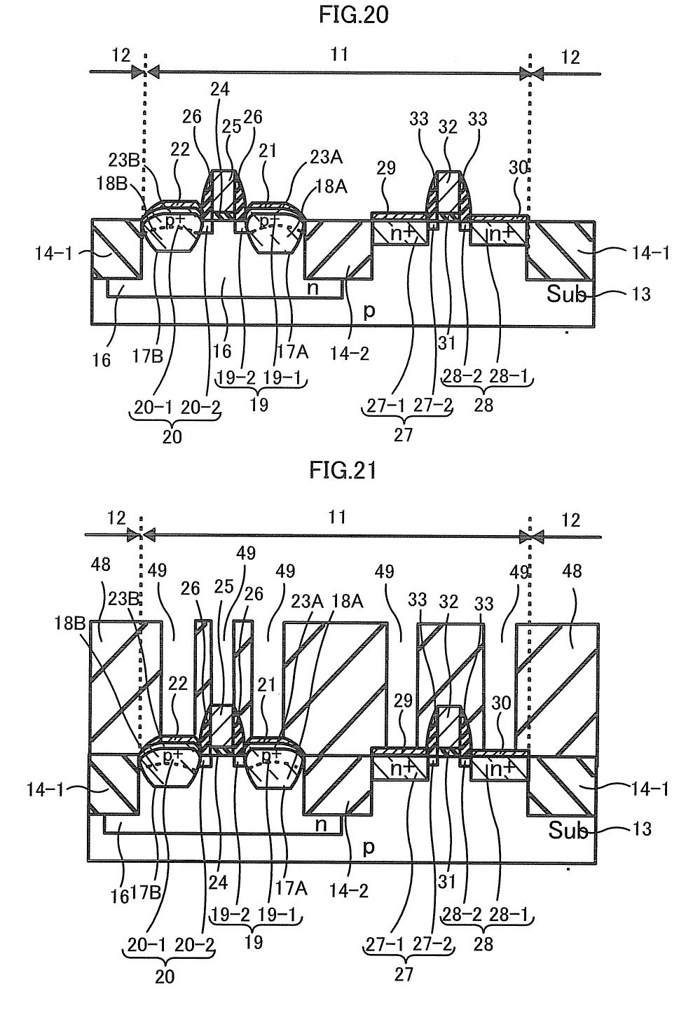

Next, other than the mixed crystal layers 18A and 18B and the n+-type impurity injection layers 27-1 and 28-1 is covered with the photo resist film (not illustrated). Thereafter, a high-melting point metal film made of nickel platinum (NiPt), for example, is formed on the mixed crystal layers 18A and 18B and the n+-type impurity injection layers 27-1 and 28-1 by using the photo resist film as the mask. Further, after removing the photo resist film (not illustrated), the annealing process is performed. According to this, as illustrated in FIG. 20, the drain electrode 21 and the source electrode 22 are formed on the mixed crystal layers 18A and 18B, respectively. Further, the drain electrode 29 and the source electrode 30 are formed on the n+-type impurity regions 27-1 and 28-1, respectively.

By the annealing process before forming the electrodes 21, 22, 29 and 30, the surface of each of the mixed crystal layers 18A and 18B is silicized. Therefore, the drain electrode 21 made of nickel platinum is formed on the silicide layer 23A on the surface of the mixed crystal layer 18A. Similarly, the source electrode 22 is formed on the silicide layer 23B on the surface of the mixed crystal layer 18B.

Next, as illustrated in FIG. 21, an interlayer insulating film 48 made of SiO₂ and the like is deposited on the surface of the silicon substrate 13. Then, a contact hole 49 is formed on each of the gate electrodes 25 and 32, the drain electrodes 21 and 29 and the source electrodes 22 and 30.

Finally, the wiring layer (not illustrated) is formed on the interlayer insulating film 48. Then, the wiring formed in the wiring layer and the gate electrodes 25 and 32 and the wiring and the drain electrodes 21 and 29 are connected, respectively, through the via (not illustrated) formed in the contact hole 49. At the same time, the source electrode 22 of the pMOSFET and the power supply (not illustrated) are connected through the via (not illustrated) formed in the contact hole 49, and the source electrode 30 of the nMOSFET is grounded through the via (not illustrated) formed in the contact hole 49. According to this, the semiconductor device according to this embodiment is formed.

According to the above-described semiconductor device, the dummy pattern 35 is formed such that the major direction thereof is different from the crystal axis <110> direction of the silicon substrate 13. The crystal axis <110> direction of the silicon substrate 13 is a direction in which binding force between the Si atoms is weak, and in general, when cleaving the silicon substrate 13, this is cleaved in this direction. In this manner, since the crystal axis <110> direction of the silicon substrate 13 is the direction in which the binding force between Si atoms is weak, the displacement and the crystal defect easily occur in this direction. Therefore, by shifting the major direction of the dummy pattern from the crystal axis <110> direction of the silicon substrate 13, the displacement and the crystal defect are inhibited from occurring on the dummy pattern 35 and on a boundary surface between the dummy pattern 35 and the silicon substrate 13 even after a variety of thermal steps in the manufacturing step of the semiconductor device and further after the flash lamp annealing step. Therefore, development of the displacement and the crystal defect from the dummy pattern 35 and the boundary surface between the dummy pattern 35 and the silicon substrate 13 to the mixed crystal layers 18A and 18B may be inhibited, and the displacement and the crystal defect occurring in the mixed crystal layers 18A and 18B may be inhibited.

Also, it is confirmed by the inventors of the present invention that a plastic deformation amount ΔBow of the silicon substrate increases when performing the high-temperature activation annealing process to the conventional silicon substrate on the surface of which the mixed crystal layer is formed.

When observing the mixed crystal layer provided on the conventional silicon substrate by an optical microscope, the displacement is observed in the crystal axis <110> direction of the silicon substrate in the mixed crystal layer. Further, the larger the mixed crystal layer is made, the higher the density of the displacement is. From this, it may be considered that the increase in the plastic deformation amount ΔBow of the silicon substrate is a phenomenon induced by the occurrence of the displacement in the mixed crystal layer. Therefore, it may be considered that the larger the mixed crystal layer is made, the more the plastic deformation amount ΔBow of the silicon substrate increases.

A reason why the silicon substrate is plastically deformed by the activation annealing is as follows. That is to say, by performing the activation annealing process in an extremely short time with the temperature increasing/decreasing rate of 10⁵° C./sec to the silicon substrate, only a temperature of the outermost layer of the silicon substrate becomes especially high and temperature difference between the outermost layer and a rear layer portion becomes large. Therefore, thermal stress occurs in a thickness direction of the silicon substrate. The silicon substrate is plastically deformed by the thermal stress.

Also, a reason why the density of the displacement becomes higher as the mixed crystal layer is made larger is considered as follows. That is to say, it is considered that a lattice mismatch factor between Si composing the silicon substrate and the mixed crystal layer increases as the mixed crystal layer becomes large, thereby increasing the stress applied in the vicinity of the mixed crystal layer.

On the other hand, according to the semiconductor device according to this embodiment, the major direction of the dummy pattern 35 of which volume is relatively large shifts from the crystal axis <110> direction of the silicon substrate 13. Therefore, the occurrence of the displacement in the dummy pattern 35 is inhibited. According to this, it becomes possible to inhibit increase in the plastic deformation amount ΔBow of the silicon substrate 13 even when the high-temperature activation annealing process is performed.

The semiconductor device according to this embodiment is described above. However, the embodiment of the present invention is not limited to this.

For example, the semiconductor element formed in the element region 11 is not limited to the CMOSFET 15. For example, the semiconductor element formed in the element region 11 may be the pMOSFET having the mixed crystal layers 18A and 18B.

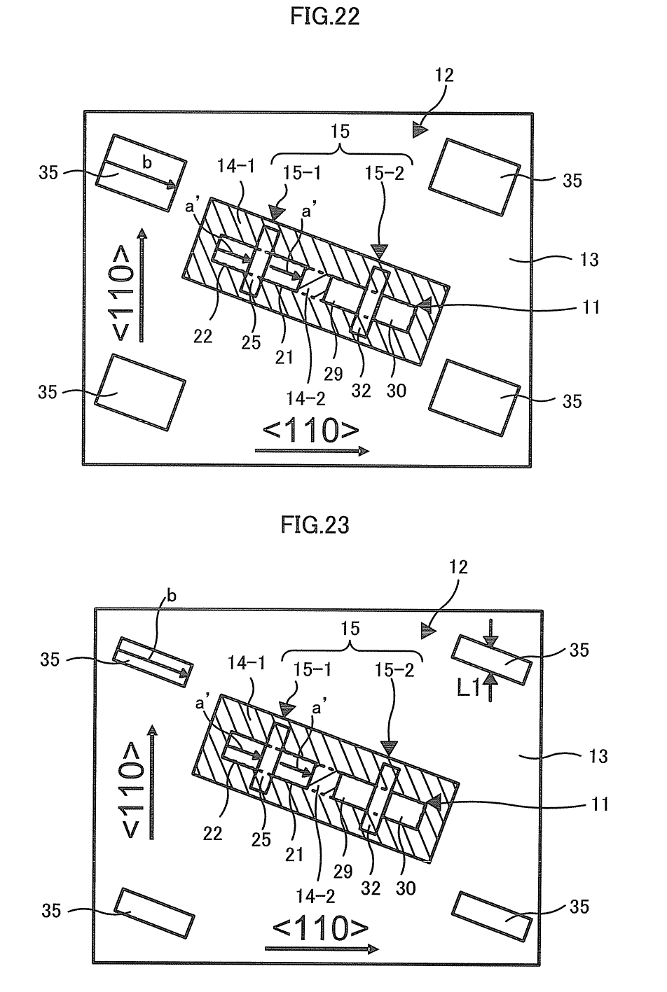

Also, the mixed crystal layers 18A and 18B formed in the semiconductor device according to the above-described embodiment may be formed such that the major directions thereof are different from the crystal axis <110> direction of the silicon substrate 13. In this case, the channel direction of the pMOSFET 15-1 is in a direction indicated by an arrow a′ in the drawing, that is to say, the direction is different from the crystal axis <110> direction of the silicon substrate 13, as illustrated in FIG. 22 in a top view. According to such semiconductor device, the displacement and the crystal defect occurring in the mixed crystal layers 18A and 18B may be more effectively inhibited.

Also, in the dummy pattern 35 formed on the semiconductor device according to the above-described embodiment, as illustrated in FIG. 23 in the top view, a length L1 in the direction along the crystal axis <110> direction of the silicon substrate 13 may be made shorter than that of the dummy pattern 35 illustrated in FIG. 22 while not changing the length in the major direction. In this manner, by making the length L1 in the direction in which the displacement and the crystal defect easily occur short, the displacement and the crystal defect occurring in the dummy pattern 35 may be more inhibited. Therefore, the displacement and the crystal defect occurring in the mixed crystal layers 18A and 18B may be more effectively inhibited.

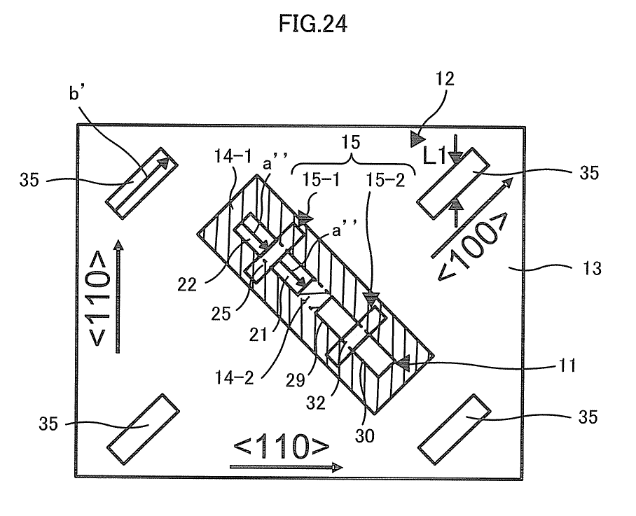

Also, the dummy pattern 35 formed on the semiconductor device according to the above-described embodiment may be formed such that the major direction thereof is in a direction indicated by an arrow b′ in the drawing, that is to say, in a crystal axis <100> direction (direction rotated from the crystal axis <110> direction by 45 degrees) of the silicon substrate 13, as compared to the dummy pattern 35 illustrated in FIG. 23, as illustrated in FIG. 24 in the top view, for example. In this manner, the displacement and the crystal defect occurring in the dummy pattern 35 may be more inhibited by forming the dummy pattern 35 such that the major direction thereof is in the crystal axis <100> direction of the silicon substrate 13 in which the displacement and the crystal defect hardly occur. Therefore, the displacement and the crystal defect occurring in the mixed crystal layers 18A and 18B may be more effectively inhibited.

Further, in FIG. 24, each of the mixed crystal layers 18A and 18B of the element region is also formed such that the major direction (arrow a″ in the drawing) thereof is in the crystal axis <100> direction of the silicon substrate 13. Therefore, the displacement and the crystal defect occurring in the mixed crystal layers 18A and 18B may be more effectively inhibited. Although both of the dummy pattern 35 and the mixed crystal layers 18A and 18B are formed in the crystal axis <100> direction of the silicon substrate 13 in the semiconductor device illustrated in FIG. 24, when at least one of the dummy pattern 35 and the mixed crystal layers 18A and 18B is formed in the crystal axis <100> direction of the silicon substrate 13, the displacement and the crystal defect occurring in the mixed crystal layers 18A and 18B may be further inhibited as compared to the semiconductor device illustrated in FIG. 1.

It is estimated that a reason why the displacement and the crystal defect occurring in the dummy pattern 35 may be further inhibited by forming the dummy pattern 35 such that the major direction of the dummy pattern 35 is in the crystal axis <100> direction of the silicon substrate 13 is as follows. That is to say, since lattice density is low in this direction, mismatch of the crystal lattice is corrected and the mismatch factor of the crystal lattice becomes small.

In this manner, it is preferable that each of the dummy pattern 35 and the mixed crystal layers 18A and 18B is in the shape in which the major direction thereof is in the crystal axis <100> direction of the silicon substrate 13 and distance in the crystal axis <110> direction of the silicon substrate 13 is short.

Although it is not described, each of the mixed crystal layers 18A and 18B is also preferably in the shape in which the major direction thereof is in the crystal axis <100> direction of the silicon substrate and the distance in the crystal axis <110> direction of the silicon substrate 13 is short as the dummy pattern 35.

Also, arrangement and number of the dummy patterns 35 may be such that the coverage, which is the ratio of the total area of the dummy patterns 35 and the mixed crystal layers 18A and 18B of the element region 11 to the surface area of the silicon substrate 13, is a rate with which normal epitaxial growth may be realized, and the arrangement and the number are not limited.

Also, in this embodiment, an annealing method using a Xe flash lamp as a thermal light source is described. However, the thermal light source is not limited to the Xe flash lamp and may be a light source capable of realizing high-intensity emission such as the flash lamp using other diluted gas, liquid silver and hydrogen, a laser such as an excimer laser, a YAG laser, a carbon monoxide (CO) gas laser and a carbon dioxide (CO₂) laser and an Xe arc discharge lamp, for example. Also, this may be applied to a case in which the thermal process is performed using the conventional halogen lamp, resistance heating heater and the like.

Although the case in which the silicon substrate 13 is used is described in this embodiment, it is not necessary to use a single-crystal wafer in bulk including the silicon substrate 13 and an epitaxial wafer, a silicon on insulator (SOI) wafer and the like may be used.

While certain embodiments have been described, these embodiments have been presented by way of example only, and are not intended to limit the scope of the inventions. Indeed, the novel devices and methods described herein may be embodied in a variety of other forms: furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
an element region provided with:
a second conductive-type transistor formed on a surface of a semiconductor and having a gate electrode and a first conductive-type drain region and a source region;
a plurality of mixed crystal layers made of a first atom composing the semiconductor substrate and a second atom having a lattice constant different from the lattice constant of the first atom, formed on both ends of a region to be a channel of the second conductive-type transistor; and
a drain electrode and a source electrode formed on the drain region and the source region, respectively;
an element isolation layer formed on the surface of the semiconductor substrate so as to enclose the element region; and
a dummy pattern made of the same material as the mixed crystal layer, formed on the surface of the semiconductor substrate outside the element isolation layer, wherein
the dummy pattern is formed such that a major direction of the dummy pattern is different from a <110> direction of the semiconductor substrate.

2. The semiconductor device according to claim 1, wherein a major direction of the dummy pattern is in a <100> direction of the semiconductor substrate.

3. The semiconductor device according to claim 1, wherein a major direction of the mixed crystal layer is different from the <110> direction of the semiconductor substrate.

4. The semiconductor device according to claim 2, wherein a major direction of the mixed crystal layer is different from the <110> direction of the semiconductor substrate.

5. The semiconductor device according to claim 1, wherein a major direction of the mixed crystal layer is in a <100> direction of the semiconductor substrate.

6. The semiconductor device according to claim 2, wherein a major direction of the mixed crystal layer is in the <100> direction of the semiconductor substrate.

7. The semiconductor device according to claim 1, wherein concentration of the second atom is the highest in the center of the mixed crystal layer.

8. The semiconductor device according to claim 2, wherein concentration of the second atom is the highest in the center of the mixed crystal layer.

9. The semiconductor device according to claim 1, wherein the element region is further provided with a first conductive-type transistor having a gate electrode and a second conductive-type drain region and a source region.

10. The semiconductor device according to claim 1, wherein a cross-sectional shape of the dummy pattern in a plane horizontal to the semiconductor substrate is a rectangle.

11. The semiconductor device according to claim 1, wherein a plurality of dummy patterns are formed on the surface of the semiconductor substrate outside the element isolation layer.

12. The semiconductor device according to claim 1, wherein the element region is further provided with a first conductive-type transistor having a gate electrode and a second conductive-type drain region and a source region.

13. A method of manufacturing a semiconductor device, comprising:
a step of forming an element isolation layer electrically isolating an element region from a non-element region on a surface of a semiconductor substrate;
a step of forming a first conductive-type impurity injection layer on a surface of the element region;
a step of forming a gate electrode on the first conductive-type impurity injection layer;
a step of forming first recess regions on both ends of a region below the gate electrode of the semiconductor substrate;
a step of forming a second recess region in the non-element region;
a step of epitaxially growing a mixed crystal layer made of a first atom composing the semiconductor substrate and a second atom having a lattice constant different from the lattice constant of the first atom in each of the first recess regions, and at the same time, epitaxially growing a dummy pattern made of the same material as the mixed crystal layer in the second recess region such that a major direction of the dummy pattern is different from a <110> direction of the semiconductor substrate;
a step of forming a second conductive-type impurity injection layer on a surface of the mixed crystal layer; and
a step of forming a drain electrode and a source electrode on the impurity injection layer.

14. The method of manufacturing the semiconductor device according to claim 13, wherein the step of epitaxially growing the dummy pattern is the step of epitaxially growing the dummy pattern in the second recess region such that a major direction of the dummy pattern is in a <100> direction of the semiconductor substrate.

15. The method of manufacturing the semiconductor device according to claim 13, wherein the step of epitaxially growing the mixed crystal layer is the step of epitaxially growing the mixed crystal layer in each of the first recess regions such that a major direction of the mixed crystal layer is different from the <110> direction of the semiconductor substrate.

16. The method of manufacturing the semiconductor device according to claim 14, wherein the step of epitaxially growing the mixed crystal layer is the step of epitaxially growing the mixed crystal layer in each of the first recess regions such that a major direction of the mixed crystal layer is different from the <110> direction of the semiconductor substrate.

17. The method of manufacturing the semiconductor device according to claim 13, wherein the step of epitaxially growing the mixed crystal layer is the step of epitaxially growing the mixed crystal layer in each of the first recess regions such that a major direction of the mixed crystal layer is in a <100> direction of the semiconductor substrate.

18. The method of manufacturing the semiconductor device according to claim 14, wherein the step of epitaxially growing the mixed crystal layer is the step of epitaxially growing the mixed crystal layer in each of the first recess regions such that a major direction of the mixed crystal layer is in the <100> direction of the semiconductor substrate.

19. The method of manufacturing the semiconductor according to claim 13, wherein the step of epitaxially growing the mixed crystal layer is the step of epitaxially growing the mixed crystal layer such that concentration of the second atom is the highest in the center of the mixed crystal layer.

20. The method of manufacturing the semiconductor device according to claim 14, wherein the step of epitaxially growing the mixed crystal layer is the step of epitaxially growing the mixed crystal layer such that concentration of the second atom is the highest in the center of the mixed crystal layer.
